(19) United States
(12) Patent Application Publication
(10) Pub. No.: US 2026/0231765 A1
(43) Pub. Date: Aug. 6, 2026

(54) STRUCTURE INCLUDING THERMAL MODULE HAVING FLOW CHANNEL

(71) Applicant: Taiwan Semiconductor Manufacturing Company, Ltd., Hsinchu (TW)

(72) Inventors: Chih-Kai Cheng, Hsinchu County (TW); Chung-Yueh Pan, Hsinchu (TW); Hung Lin Chen, Taipei City (TW)

(73) Assignee: Taiwan Semiconductor Manufacturing Company, Ltd., Hsinchu (TW)

(21) Appl. No.: 19/045,552

(22) Filed: Feb. 5, 2025

(51) Int. Cl. H01L 23/473

(52) U.S. Cl. CPC H10W 40/47

(57) ABSTRACT

A structure includes a thermal module and an electronic component intermediate is provided. The thermal module has a flow channel. The electronic component intermediate is disposed on and thermally coupled to the thermal module.

### BACKGROUND

In a manufacturing process of electronic components, it is often necessary to place a corresponding structure (e.g., an electronic component intermediate) on an appropriate carrier, and then adjust the temperature of the structure disposed on the carrier according to a corresponding requirement of the process. As such, an appropriate tool (such as including a corresponding module or kit) is actually desired for efficient and/or convenient to be performed the aforementioned process or step.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a portion of cross-section view of a process intermediate of an embodiment of the disclosure.

FIG. 2 illustrates a stereoscopic view of a thermal module of an embodiment of the disclosure.

FIG. 3A illustrates a stereoscopic exploded view of a thermal module of an embodiment of the disclosure.

FIG. 3B illustrates a portion of cross-section view of a thermal module of an embodiment of the disclosure.

FIG. 4A illustrates a portion of cross-section view of a thermal module of an embodiment of the disclosure.

FIG. 4B illustrates a portion of top view of a thermal module of an embodiment of the disclosure.

FIG. 5 illustrates a portion of cross-section view of a process of an embodiment of the disclosure.

FIG. 6A illustrates a stereoscopic exploded view of a thermal module of an embodiment of the disclosure.

FIG. 6B illustrates a portion of cross-section view of a thermal module of an embodiment of the disclosure.

FIG. 7 illustrates a portion of cross-section view of a process of an embodiment of the disclosure.

FIG. 8 illustrates a portion of flow for a manufacturing method of an electronic component of an embodiment of the disclosure.

### DETAILED DESCRIPTION

The following disclosure provides many different embodiments or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the component in use or operation in addition to the orientation depicted in the figures. The apparatus may be otherwise oriented (rotated 90 degrees or at other orientations) and the spatially relative descriptors used herein may likewise be interpreted accordingly.

It will be understood that, although the terms “first”, “second”, “third” and the like, may be used herein to describe various elements, these elements should not be limited by these terms. These terms are only used to distinguish one element from another. For example, a first element may be referred to as a second element, and similarly, a second element may be referred to as a first element without departing from the scope of protection of the inventive concept.

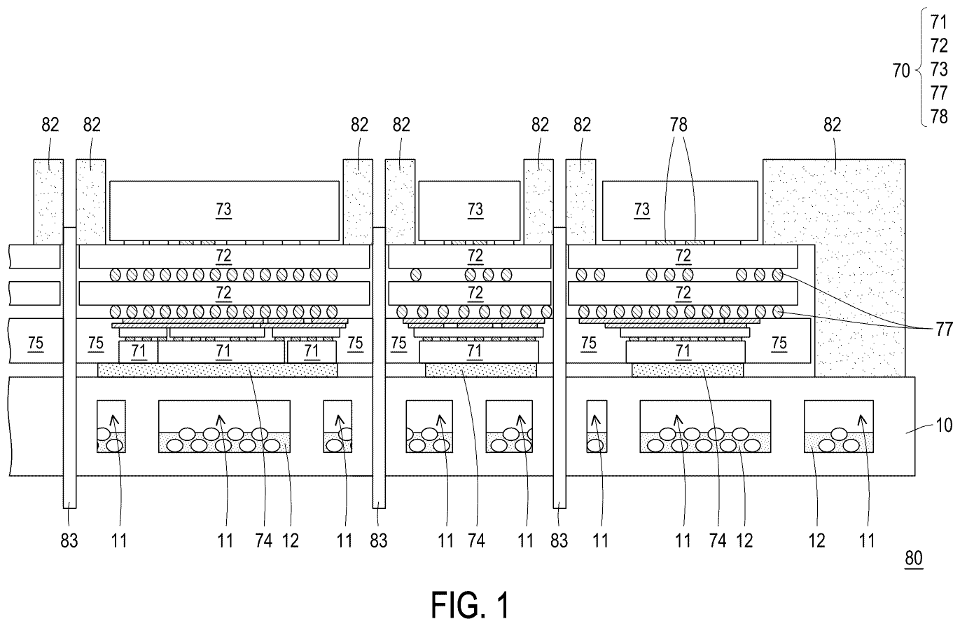

In an embodiment, in a manufacturing process of an electronic component, one or more process intermediates (e.g., a structure as shown in FIG. 1) including corresponding one or more tools could be provided or obtained. By combining or using the aforementioned one or more tools (e.g., a thermal module described later), the aforementioned process intermediate could be suitable for an appropriate process (e.g., heating, cooling, transferring, flipping, etc.).

FIG. 1 illustrates a process intermediate of an embodiment of the disclosure. An electronic component intermediate 70 could be combined with one or more tools for being a process intermediate 80. That is, a process intermediate 80 may include one or more electronic component intermediates 70 and one or more tools corresponding to at least one of the one or more electronic component intermediate 70.

Referring to FIG. 1, a system-on-wafer assembly (e.g., a kind of a process intermediate 80) is formed by clamping a package component (e.g., a kind of an electronic component intermediate 70) between a thermal module 10 (e.g., a kind of a tool) and a mechanical brace 82 (e.g., another kind of a tool). The mechanical brace 82 could by applied with one or more mechanical components 83 (e.g., a bolt, a fastener, a nut, a screw, etc.). Clamping could be performed by initially fastening the thermal module and mechanical brace 82 with the one or more mechanical components 83 at a low torque. The one or more mechanical components 83 could be then adjusted to fill gaps between the mechanical brace 82 and the electronic component intermediate 70. By increasing the mechanical support, the mechanical brace 82 may exert a more uniform pressure profile on the electronic component intermediate 70 and thermal module 10, thereby increasing the thermal transfer for the electronic component intermediate 70 (e.g., for heating or cooling the electronic component intermediate 70).

In an embodiment, the electronic component intermediate 70 is disposed on the thermal module 10. For example, the electronic component intermediate 70 is secured between the thermal module 10 and a mechanical brace 82. The mechanical brace 82 could be a rigid support that may be formed from a material with a high stiffness, such as a metal, e.g., steel, titanium, cobalt, or the like. The mechanical brace 82 may include a frame or a clamp for securing the electronic component intermediate 70. In an embodiment, warpage of the electronic component intermediate 70, such as that induced by carrier substrate debonding, may be reduced by clamping the electronic component intermediate 70 between the thermal module 10 and mechanical brace 82. Some details are omitted in FIG. 1 for clarity of illustration. For example, one or more appropriate mechanical component (e.g., a bolt, a fastener, a nut, a screw, etc.) the same or similar to the mechanical components 83 as shown in FIG. 1 could be provided for securing the electronic component intermediate 70 between the mechanical brace 82 and the thermal module 10.

In an embodiment, the electronic component intermediate 70 includes an encapsulant 75 and one or more dies 71. The die 71 at least includes an integrated circuit (IC) die; or, further include a dummy die. Two of the integrated circuit dies may be heterogeneous dies or homogeneous dies. The integrated circuit die may be a logic die (e.g., application processor (AP), central processing unit (CPU), graphics processing unit (GPU), microcontroller, system-on-a-chip (SoC), etc.), a memory die (e.g., dynamic random access memory (DRAM) die, static random access memory (SRAM) die, etc.), an input/output (I/O) die, a power management die (e.g., power management integrated circuit (PMIC) die), a radio frequency (RF) die, a sensor die, a micro-electro-mechanical-system (MEMS) die, a signal processing die (e.g., digital signal processing (DSP) die), a front-end die (e.g., analog front-end (AFE) dies), an application-specific die (e.g., an application-specific integrated circuit (ASIC), a field-programmable gate array (FPGA), etc.), the like, or combinations thereof. A material of the encapsulant 75 may include polymer, for example, epoxy. The material for forming the encapsulant 75 could be cured by an appropriate method (e.g., heating), so that the one or more dies 71 could be fixed therein.

In an embodiment, the electronic component intermediate 70 further include one or more circuit structure 72. The circuit structure 72 may be a circuit board, an interposer, the like, or combinations thereof. One or more corresponding circuits could be redistributed through the circuit structure 72. A corresponding circuit of the circuit structure 72 could be coupled to the die 71 by one or more connectors 77. For clarity, not all connectors 77 are labelled in the FIG. 1. A material of the connector may include a bonding material, for example, solder, but the disclosure is not limited thereto. In an embodiment, the connector 77 may include a solder ball, a solder bump, the like, or combinations thereof, but the disclosure is not limited thereto. By heating and then cooling the bonding material, the circuit structure 72 and the die 71 could be directly or indirectly bonded with each other.

In an embodiment, the electronic component intermediate 70 further include one or more electronic device 73. The die 71 and the electronic device 73 may be heterogeneous or homogeneous components/devices/elements. The electronic device 73 may be a system-on-a-chip (SoC), a high bandwidth memory (HBM), a power management module (e.g., voltage regulator module (VRM)), an input/output (I/O) module, a connector module, the like, or combinations thereof (e.g., an IO-VRM module). In an embodiment, a corresponding circuit of the circuit structure 72 could be coupled to the electronic device 73 by one or more connectors 78 the same or similar to the aforementioned connector 77. For clarity, not all connectors 78 are labelled in the FIG. 1.

In an embodiment, the electronic component intermediate 70 further include a substrate (not shown). The substrate may be a wafer, a panel, or a suitable carrier, but the disclosure is not limited thereto. An electronic component intermediate 70 including a wafer (e.g., a silicon wafer) and one or more electronic components/devices/elements (e.g., the aforementioned die 71 and/or device 73) disposed thereon may be referred as a system-on-wafer (SoW) structure. An electronic component intermediate 70 including a panel (e.g., a glass panel) and one or more electronic components/devices/elements (e.g., the aforementioned die 71 and/or device 73) disposed thereon may be referred as a system-on-panel (SoP) structure.

In an embodiment, a thermal interface material (TIM) 74 (e.g., a TIM film) is disposed between the electronic component intermediate 70 and the thermal module 10, but the disclosure is not limited thereto.

The electronic component intermediate 70 is disposed on and/or thermally coupled to the thermal module 10. In an embodiment, during a corresponding process, a heating step or a cooling step is performed for forming the electronic component intermediate 70. In an embodiment, the electronic component intermediate 70 disposed on and/or thermally coupled to the thermal module 10 is treated by a heating step or a cooling step. In an embodiment, during the corresponding process, the thermal module 10 may be referred as a heating/cooling sink, a heating/cooling spreader, a heating/cooling plate, or the like.

The thermal module 10 has a flow channel 11 inside thereof. The pattern, width, and/or height of the flow channel 11 could be adjusted according to corresponding requirements. The flow channel 11 allows fluid 12 with appropriate temperature to flow therein. The fluid 12 may be in a gaseous state, a liquid state, or a mixture thereabove. The type and/or flow rate of fluid 12 could be adjusted according to corresponding requirements. In an embodiment, the composition of the fluid 12 may include appropriate additives. For example, antifreeze (a type of the aforementioned additive) may reduce the probably of liquid (e.g., a type of the fluid 12) freezing. For example, particles (a type of the aforementioned additive) may reduce the probably of liquid (e.g., a type of the fluid 12) bumping.

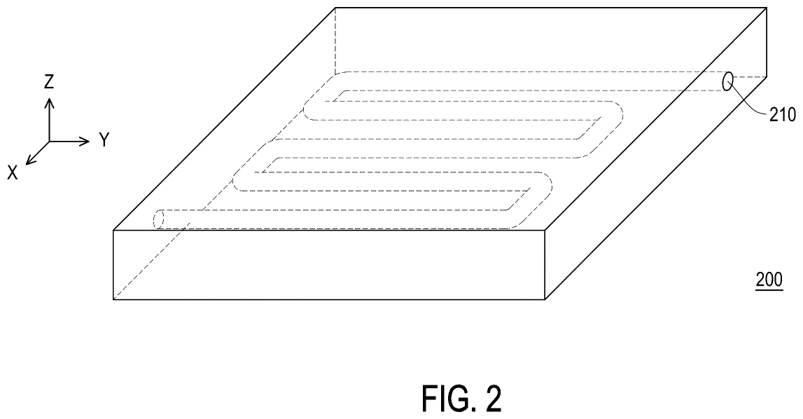

FIG. 2 illustrates a stereoscopic view of a thermal module of an embodiment of the disclosure. The thermal module 200 as shown in FIG. 2 could be a type of the aforementioned thermal module 10. Therefore, an application method of the thermal module 200 could be referred to the description corresponding to FIG. 1.

The thermal module 200 has a flow channel 210. The flow channel 210 allows fluid (e.g., the same or similar to the aforementioned fluid 12) with appropriate temperature to flow therein, so that the thermal module 200 has a corresponding temperature, and a structure (e.g., the same or similar to the aforementioned electronic component intermediate 70) disposed thereon could be heated or cooled. The pattern, width, and/or height of the flow channel 210 could be adjusted according to corresponding requirements (e.g., type of fluid, temperature for application), and are not limited in the disclosure.

In an embodiment, the thermal module 200 is a combination of a plurality of modules. For example, one of the separated modules has a corresponding recessed area or a corresponding trench. Therefore, the module having the corresponding recessed area or the corresponding trench could be combined with one or more other module, as such to be the thermal module 200.

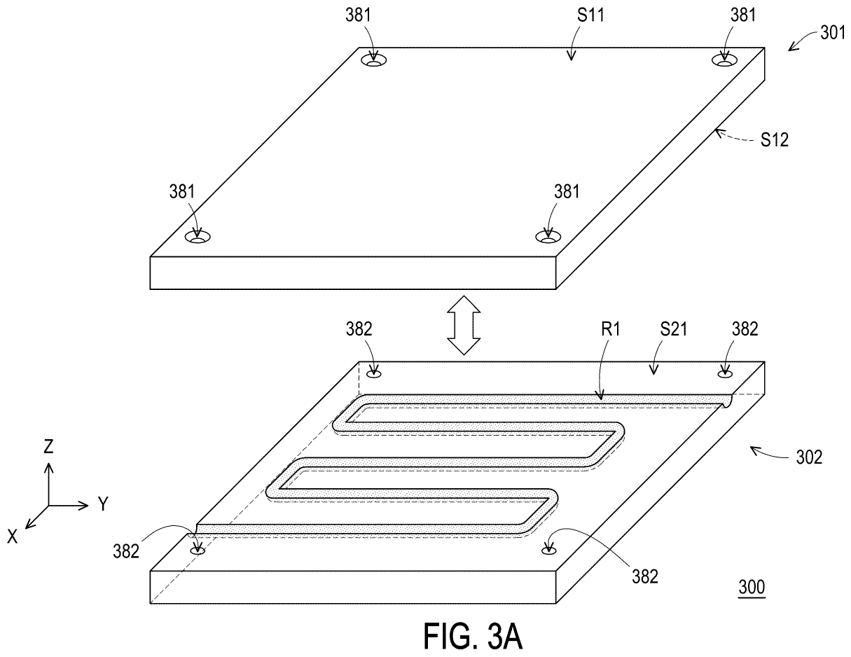

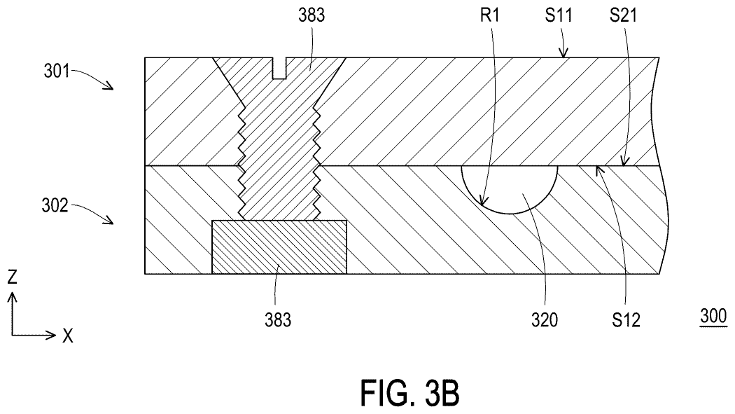

FIG. 3A illustrates a stereoscopic exploded view of a thermal module of an embodiment of the disclosure. FIG. 3B illustrates a portion of cross-section view of a thermal module of an embodiment of the disclosure. The thermal module 300 as shown in FIGS. 3A and/or 3B could be a type of the aforementioned thermal module 10. Therefore, an application method of the thermal module 300 could be referred to the description corresponding to FIG. 1.

As shown in FIGS. 3A and 3B, the thermal module 300 include a first module 301 and a second module 302. The first module 301 and the second module 302 may respectively have corresponding combination holes 381, 382 for combining with each other. For example, a mechanical component (e.g., a bolt, a fastener, a nut, a screw, etc.) 383 could be embedded in or penetrated through the combination hole for securing the first module 301 and the second module 302. For clarity, only four combination holes corresponding to the corner of each separated module (e.g., the first module 301 and the second module 302) are shown in FIG. 3A, but the number, location, size and/or shape of the combination holes is/are not limited in the disclosure.

In an embodiment, the first module 301 and the second module 302 may respectively further have other one or more holes (not shown) for combining other structure (e.g., the mechanical brace 82 as shown in FIG. 1), but the disclosure is not limited thereto.

In an embodiment, the second module 302 has a recessed area R1 on the first surface S21 thereof. The recessed area R1 could be formed by an appropriate method. Taking the second module 302 made of metal (e.g., copper) as an example, the recessed area R1 could be formed by drilling, grinding, scoring, and/or etching. The pattern, width, and/or depth of the recessed area R1 could be adjusted according to corresponding requirements. Taking FIG. 3A for example, the recessed area R1 may include corresponding strip patterns, but the disclosure is not limited thereto.

In an embodiment, the first module 301 has a second surface S12, and the first module 301 and the second module 302 could be combined with the second surface S12 facing the first surface S21. As such, after combining the first module 301 and the second module 302, the recessed area R1 on the first surface S21 and the second surface S12 could form one or more corresponding flow channels 320, for example, as shown in FIGS. 3A and 3B.

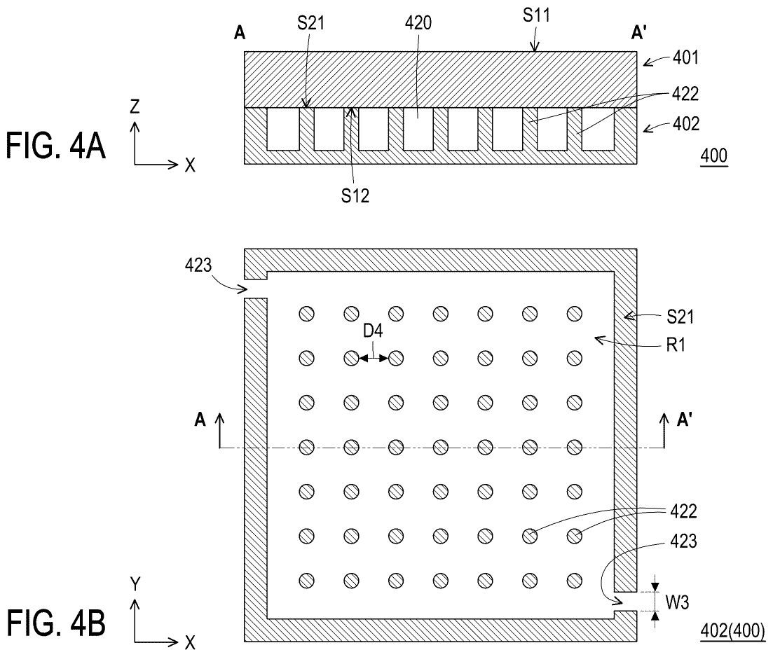

FIG. 4A illustrates a portion of cross-section view of a thermal module of an embodiment of the disclosure. FIG. 4B illustrates a portion of top view of a thermal module of an embodiment of the disclosure. The thermal module 400 as shown in FIGS. 4A and/or 4B could be a type of the aforementioned thermal module 10. Therefore, an application method of the thermal module 400 could be referred to the description corresponding to FIG. 1.

As shown in FIGS. 4A and 4B, the thermal module 400 include a first module 401 and a second module 402. FIG. 4A illustrates a portion of cross-section view of a thermal module 400 corresponding to combine the first module 401 and the second module 402. FIG. 4B illustrates a portion top view of a second module 402. The cross-section view as shown in FIG. 4A may correspond to the A-A′ cross-section line as shown in FIG. 4B.

In an embodiment, the second module 402 has a recessed area R1 on the first surface S21 thereof. In a top view (e.g., as shown in FIG. 4B), the recessed area R1 occupies more than half of the first surface S1, and could be regarded as a corresponding cavity. One or more pillars 422 are configurated in the cavity. The configuration, location, number, and appearance of the pillars 422 could be adjusted according to corresponding requirements (e.g., type of fluid, temperature for application).

Considering flow efficiency of the fluid (e.g., reducing turbulence), in an embodiment, the openings 423 do not overlap to any one of the pillars 422 in the flow inlet/outlet direction (e.g., the X direction as shown in the figure); and/or, the distance D4 between two of the pillars 422 is larger than the width W3 of the openings 423.

When the first module 401 and the second module 402 are combined, the top of the pillar 422 may be in contact with the second surface S12 of the first module 401, but the disclosure is not limited thereto.

Referring to FIGS. 3A, 3B, 4A and/or 4B, in an embodiment, the first module 301, 401 has a third surface S11 opposite to the second surface S12. A structure expected to be heated and/or cooled could be placed on the third surface S11 of the first module 301, 401. Moreover, the second surface S12 of the first module 301, 401 may be substantially flat. The term “substantially flat” for the second surface S12 means, for example, that when the second surface S12 faces the first surface S21, the area corresponding to the recessed area R1 in the second surface may be flat. That is, the first surface S21 and/or the second surface S12 may have other corresponding areas suitable for combining the first module 301, 401 and the second module 302, 402. For example, a hole area for insert mechanical component (e.g., a bolt, a fastener, a nut, a screw, etc.). Through the aforementioned configuration, it may be unnecessary to transfer the structure placed on the third surface S11 during the manufacturing process, and the pattern, width, and/or height of the flow channel could be adjusted according to corresponding requirements by replacing the second module 302, 402.

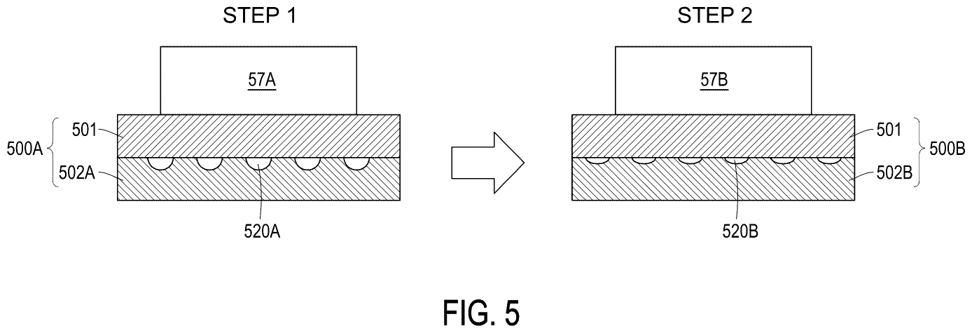

For example, as shown in FIG. 5, the structure 57A is placed on the thermal module 500A during step 1, and the structure 57B is placed on the thermal module 500B during step 2. The structure 57A could be substantially the same or similar to the structure 57B. For example, the structure 57B may be formed or obtained from the structure 57A through a corresponding process. The thermal module 500A includes a first module 501 and a second module 502A, the thermal module 500B includes the first module 501 and a second module 502B, the first module 501 of the thermal module 500A and the first module 501 of the thermal module 500B is a same module, and the second module 502B of the thermal module 500A and the second module 502B of the thermal module 500B are different. The pattern, width, and/or height of flow channels 520A, 502B between the thermal module 500A and the thermal module 500B are different.

A flow channel (e.g., the flow channel of the thermal module) with a larger cross-sectional area (e.g., larger width, and/or height) could be suitable for a fluid with higher viscosity coefficient, and a flow channel with a smaller cross-sectional area (e.g., smaller width, and/or height) could be suitable for a fluid with lower viscosity coefficient.

Since the boiling point of water is 100° C. (generally being controlled in a range of about 5° C.~80° C. for heating or cooling), so although silicone oil has a higher (comparing with water) viscosity coefficient, silicone oil could be used in a higher (comparing with water) temperature process. For example, a fluid (e.g., silicone oil) with higher viscosity coefficient could flow through the flow channel 520A during step 1 with higher process temperature (e.g., a heating temperature to higher than or equal to 80° C., or a cooling temperature from higher than or equal to 80° C.); and, a fluid with lower viscosity coefficient could flow through the flow channel 520B during step 2 with lower process temperature (e.g., a heating temperature to lower than or equal to 80° C., or a cooling temperature from lower than or equal to 80° C.).

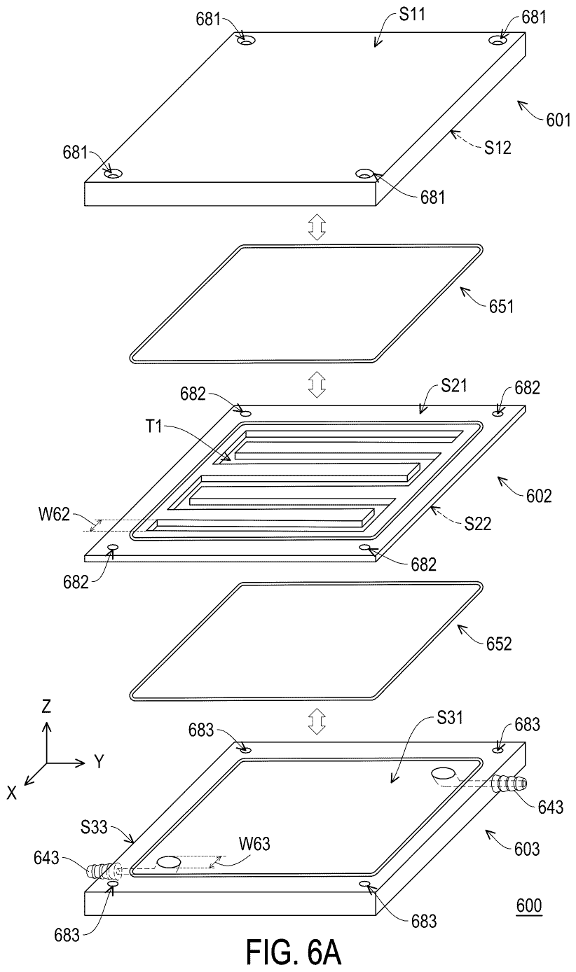

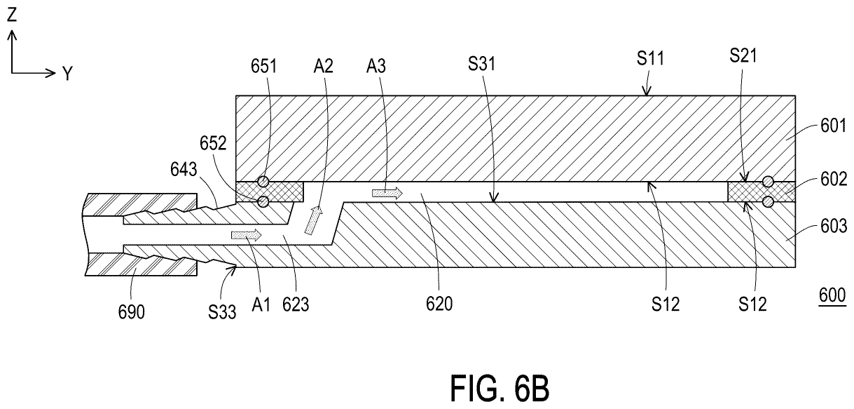

FIG. 6A illustrates a portion of cross-section view of a thermal module of an embodiment of the disclosure. FIG. 6B illustrates a portion of top view of a thermal module of an embodiment of the disclosure. The thermal module 600 as shown in FIGS. 6A and/or 6B could be a type of the aforementioned thermal module 10. Therefore, an application method of the thermal module 600 could be referred to the description corresponding to FIG. 1.

As shown in FIGS. 6A and 6B, the thermal module 600 600 include a first module 601, a second module 602, and a third module 603. The first module 601, the second module 602, and the third module 603 may respectively have corresponding combination holes 681, 682, 683 for combining with each other. For example, a mechanical component (e.g., a bolt, a fastener, a nut, a screw, etc.) could be embedded in or penetrated through the combination hole 681, 682, 683 for securing the second module 602 sandwich between the first module 601 and the third module 603. For clarity, only four combination holes corresponding to the corner of each separated module (e.g., the first module 601, the second module 602, and the third module 603) are shown in FIG. 6A, but the number, location, size and/or shape of the combination holes is/are not limited in the disclosure.

In an embodiment, the first module 601, the second module 602, and the third module 603 may respectively further have other one or more holes (not shown) for combining other structure (e.g., the mechanical brace 82 as shown in FIG. 1), but the disclosure is not limited thereto.

In an embodiment, the second module 602 has a trench T1 penetrated therethrough. That is, a height of the trench T1 substantially equal to the thickness of the second module 602. The trench T1 could be formed by an appropriate method. Taking the second module 602 made of metal (e.g., copper) as an example, the trench T1 could be formed by punching, drilling, grinding, scoring, and/or etching. The pattern and/or width of the trench T1 could be adjusted according to corresponding requirements. Taking FIG. 6A for example, the trench T1 may include corresponding strip patterns, but the disclosure is not limited thereto.

In an embodiment, the first module 601 has a second surface S12, the third module 603 has a fifth surface S31, the first module 601 and the second module 602 could be combined with the second surface S12 facing a first surface S21 of the second module 602, and the third module 603 and the second module 602 could be combined with the fifth surface S31 facing a fourth surface S22 of the second module 602. As such, after combining the first module 601, the second module 602 and the third module 603, the second surface S12 of the first module 601, the trench T1 of the second module 602, and fifth surface S31 of the third module 603 could form one or more corresponding flow channels 620, for example, as shown in FIGS. 6A and 6B.

In an embodiment, the third module 603 has at least one guiding hole 623. An end of the guiding hole 623 is located on the fifth surface S31, and corresponding to the trench T1 of the second module 602. For clarity, in the third module 603 as shown in FIG. 6, the shape or position of the guiding hole 623 within the third module 603 are plotted with a dotted line.

In an embodiment, a width W62 of the trench T1 (the dimension of the trench T1 in a direction, for example Y direction, substantially perpendicular to the flow direction) is narrower than an aperture width W63 at the end of the guiding hole 623 (the dimension of the aperture substantially parallel to the aforementioned direction). As such, alignment between the second module 602 and the third module 603 could be simpler or faster. Moreover, the third module 603 could be applied with different second modules with different trenches having different pattern and/or width.

In an embodiment, another end of the guiding hole 623 is located on a surface different from the fifth surface S31. For example, the end of the guiding hole 623 is located on a side surface S33 substantially perpendicular to fifth surface S31.

In an embodiment, the third module 603 include one or more fluid connectors 643 located on a surface different from the fifth surface S31. The end of the guiding hole 623 is located on the terminal of the fluid connector 643. The fluid connector 643 is suitable for connection to a corresponding fluid pipe 690.

In an embodiment, the guiding hole 623 is formed by a drilling process, for example, drill holes separately from different surfaces and connect them to form a corresponding guiding hole 623. Therefore, the guiding hole 623 could be formally divided into different sections with different directions.

In an embodiment, along the flow direction, an included angle between the extension directions of two adjacent sections is less than 90°. In this way, flow efficiency of the fluid may be improved (e.g., reducing turbulence). Taking FIG. 6B as an example, the arrows are shown as the flow directions of injected fluid corresponding to different sections. The included angle between the direction of arrow A1 and the direction of arrow A2 is less than 90°, and/or the included angle between the direction of arrow A2 and the direction of arrow A3 is less than 90°.

Referring to FIGS. 6A and/or 6B, in an embodiment, the fifth surface S31 of the third module 603 may be substantially flat. The term “substantially flat” for the fifth surface S31 means, for example, that when the fifth surface S31 faces the fourth surface S22, the area corresponding to the trench T1 in the fifth surface S31 may be flat. That is, the fourth surface S22 and/or the fifth surface S31 may have other corresponding areas suitable for combining the second module 602 and the third module 603. For example, a hole area for insert mechanical component (e.g., a bolt, a fastener, a nut, a screw, etc.), or a recessed area for embedding a sealing component 652 (e.g., an O-ring).

Referring to FIGS. 6A and/or 6B, in an embodiment, the first module 601 has a third surface S11 opposite to the second surface S12. A structure expected to be heated and/or cooled could be placed on the third surface S11 of the first module 601. Moreover, the second surface S12 of the first module 601 may be substantially flat. The term “substantially flat” for the second surface S12 means, for example, that when the second surface S12 faces the first surface S21, the area corresponding to the trench T1 in the second surface S12 may be flat. That is, the first surface S21 and/or the second surface S12 may have other corresponding areas suitable for combining the first module 601 and the second module 602. For example, a hole area for insert mechanical component (e.g., a bolt, a fastener, a nut, a screw, etc.), or a recessed area for embedding a sealing component 651 (e.g., an O-ring). Through the aforementioned configuration, it may be unnecessary to transfer the structure placed on the third surface S11 during the manufacturing process, and the pattern, width, and/or height of the flow channel 620 could be adjusted according to corresponding requirements by replacing the second module 602.

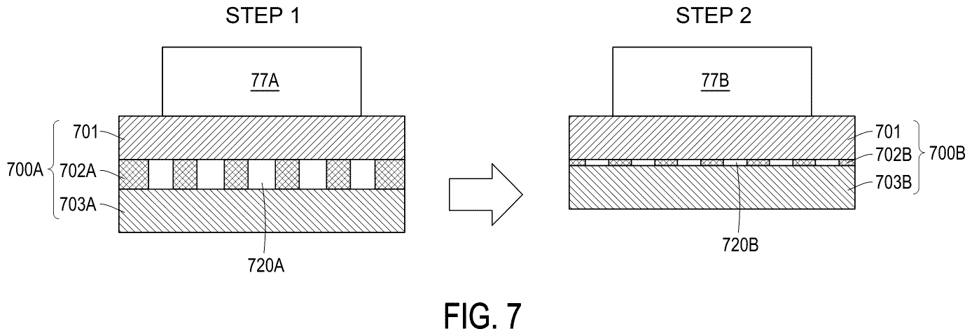

For example, as shown in FIG. 7, the structure 77A is placed on the thermal module 700A during step 1, and the structure 77B is placed on the thermal module 700B during step 2. The structure 77A could be substantially the same or similar to the structure 77B. For example, the structure 77B may be formed or obtained from the structure 77A through a corresponding process. The thermal module 700A includes a first module 701, a second module 702A, and a third module 703A. The thermal module 700B includes the first module 701, a second module 702B, and a third module 703B. The first module 701 of the thermal module 700A and the first module 701 of the thermal module 700B is a same module. The second module 702B of the thermal module 700A and the second module 702B of the thermal module 700B are different. The third module 703A of the thermal module 700A and the third module 703B of the thermal module 700B could be the same or different, the disclosure is not limited thereto. The pattern, width, and/or height of flow channels 720A, 702B between the thermal module 700A and the thermal module 700B are different.

A flow channel (e.g., the flow channel 720A of the thermal module 700A) with a larger cross-sectional area (e.g., larger width, and/or height) could be suitable for a fluid with higher viscosity coefficient, and a flow channel (e.g., the flow channel 720B of the thermal module 700B) with a smaller cross-sectional area (e.g., smaller width, and/or height) could be suitable for a fluid with lower viscosity coefficient. For example, a fluid (e.g., silicone oil) with higher viscosity coefficient could flow through the flow channel 720A during step 1 with higher process temperature (e.g., a heating temperature to higher than or equal to 80° C., or a cooling temperature form higher than or equal to 80° C.), and a fluid with lower viscosity coefficient could flow through the flow channel 720B during step 2 with lower process temperature (e.g., a heating temperature to lower than or equal to 80° C., or a cooling temperature form lower than or equal to 80° C.).

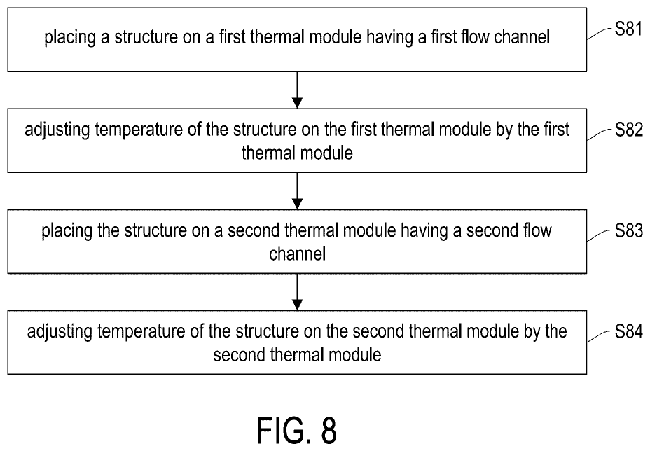

FIG. 8 illustrates a portion of flow for a manufacturing method of an electronic component of an embodiment of the disclosure.

At act S81, a structure is placed on a first thermal module having a first flow channel. Step 1 in FIGS. 5 and/or 7 illustrates a cross-sectional view corresponding to various embodiments of act S81.

In an embodiment, the structure is the same or similar to the electronic component intermediate 70 or further the process intermediate 80 as shown in FIG. 1; and, the first thermal module is the same or similar to the thermal module 10 as shown in FIG. 1, for example, the thermal module 200 as shown in FIG. 2, the thermal module 300 as shown in FIGS. 3A and 3B, the thermal module 400 as shown in FIG. 4, or the thermal module 600 as shown in FIG. 6.

At act S82, temperature of the structure on the first thermal module is adjusted by the first thermal module.

At act S83, the structure is placed on a second thermal module having a second flow channel. Step 2 as shown in FIGS. 5 and/or 7 illustrates a cross-sectional view corresponding to various embodiments of act S83.

In an embodiment, the structure is the same or similar to the electronic component intermediate 70 or further the process intermediate 80 as shown in FIG. 1; and, the second thermal module is the same or similar to the thermal module 10 as shown in FIG. 1, for example, the thermal module 200 as shown in FIG. 2, the thermal module 300 as shown in FIGS. 3A and 3B, the thermal module 400 as shown in FIG. 4, or the thermal module 600 as shown in FIG. 6.

At act S84, temperature of the structure on the second thermal module is adjusted by the second thermal module.

In an embodiment, a portion of the first thermal module and a portion of the thermal module is a same sub-module; and, another portion of the first thermal module and another portion of the thermal module are same sub-modules. For example, as shown in FIG. 5, the first thermal module (500A as shown in FIG. 5) includes an upper module (501 as shown in FIG. 5) and a first lower module (502A as shown in FIG. 5); the second thermal module includes the upper module (501 as shown in FIG. 5) and a second lower module (502B as shown in FIG. 5); and, the first lower module and the second lower module are different. For example, as shown in FIG. 7, the first thermal module (700A as shown in FIG. 7) includes an upper module (701 as shown in FIG. 7), a first lower module (702A as shown in FIG. 7), and a first bottom module (703A as shown in FIG. 7); the second thermal module includes the upper module (701 as shown in FIG. 7), a second lower module (702B as shown in FIG. 7), and a second bottom module (703B as shown in FIG. 7); and, the first lower module and the second lower module are different.

In an embodiment, the aforementioned first thermal module and the aforementioned second thermal module constitute a thermal module kit having a same upper module for the structure disposed thereon.

In an embodiment, a temperature adjustment rate (e.g., temperature change per unit time) in act S82 is different a temperature adjustment rate in act S84.

In an embodiment, a highest temperature in act S82 is different a highest temperature in act S84; and/or, a lowest temperature in act S82 is different a lowest temperature in act S84.

In an embodiment, the structure corresponding to act S82 is the same or formed from the structure corresponding to act S81; the structure corresponding to act S83 is the same or formed from the structure corresponding to act S82; and/or, the structure corresponding to act S84 is the same or formed from the structure corresponding to act S83. Structures 500A/500B and/or 700A/700B as respectively shown in FIGS. 5 and/or 7 are illustrated for example.

In an embodiment, the thermal module of the disclosure would be removed after performing the corresponding process. That is, there will be no thermal module the same or similar to the aforementioned thermal module 10 in a final product. That is, the thermal module could be a temporary tool during the manufacturing process.

In accordance with some embodiments of the present disclosure, a structure includes a thermal module and an electronic component intermediate. The thermal module has a flow channel. The electronic component intermediate is disposed on and thermally coupled to the thermal module. In an embodiment, the flow channel is located inside the thermal module. In an embodiment, the thermal module includes a first module and a second module, and wherein: the first module has a first top surface, a first bottom surface opposite to the first top surface, and a first combination hole penetrated through the first top surface and the first bottom surface; the second module has a second top surface, a second bottom surface opposite to the second top surface, and a second combination hole penetrated through the second top surface and the second bottom surface; and the first combination hole and the second combination hole are corresponded for combination the first module and the second module. In an embodiment, the thermal module includes a first module and a second module, and wherein: the second module has a top surface, and a recessed area on the top surface. In an embodiment, the first module has a bottom surface, and wherein a portion of the bottom surface corresponding to the recessed area is substantially flat. In an embodiment, the thermal module includes a first module, a second module, and a third module, and wherein: the second module is disposed between the first module and the third module; and the second module has a trench, for forming the flow channel with the first module and the third module. In an embodiment, the thermal module further includes at least one sealing component disposed between the first module and the second module, and/or disposed between the second module and the third module. In an embodiment, the thermal module has a guiding hole connecting to the flow channel. In an embodiment, the thermal module includes a fluid connector, wherein an end of the guiding hole is located on a terminal of the fluid connector.

In accordance with some embodiments of the present disclosure, a thermal module kit includes a first thermal module and a second thermal module. The first thermal module has a first flow channel. The second thermal module has a second flow channel. The first flow channel and the second flow channel are different in pattern, width and/or height. In an embodiment, an upper module and a first lower module constitute the first thermal module; the upper module and a second lower module constitute the second thermal module; and the first lower module and the second lower module are different. In an embodiment, a first upper module and a first lower module constitute the first thermal module; a second upper module and a second lower module constitute the second thermal module; and a surface of the first upper module facing to the first lower module and a surface of the second upper module facing to the second lower module are substantially flat. In an embodiment, a first upper module, a first lower module, and a first bottom module constitute the first thermal module, wherein first lower module is disposed between the first upper module and the first bottom module, and the first lower module has a first trench for forming the first flow channel with the first upper module and the first bottom module; and a second upper module, a second lower module, and a second bottom module constitute the second thermal module, wherein second lower module is disposed between the second upper module and the second bottom module, and the second lower module has a second trench for forming the second flow channel with the second upper module and the second bottom module. In an embodiment, the first bottom module and the second bottom module are a same module having a guiding hole, wherein an aperture width at an end of the guiding hole is wider than widths of the first flow channel and the second flow channel. In accordance with some embodiments of the present disclosure, a method for manufacturing an electronic component includes: placing a structure on a first thermal module having a first flow channel; and adjusting temperature of the structure on the first thermal module by the first thermal module. In an embodiment, the method further includes: placing the structure on a second thermal module having a second flow channel; and adjusting temperature of the structure on the second thermal module by the second thermal module, wherein: the first flow channel and the second flow channel are different in pattern, width and/or height. In an embodiment, the method further includes: placing the structure on a second thermal module having a second flow channel; and adjusting temperature of the structure on the second thermal module by the second thermal module, wherein: a highest temperature of the structure on the first thermal module is different a highest of the structure on the second thermal module; or a lowest temperature of the structure on the first thermal module is different a lowest of the structure on the second thermal module. In an embodiment, the method further includes: placing the structure on a second thermal module having a second flow channel; and adjusting temperature of the structure on the second thermal module by the second thermal module, wherein: a temperature adjustment rate of the structure on the first thermal module is different a temperature adjustment rate of the structure on the second thermal module. In an embodiment, the method further includes: placing the structure on a second thermal module having a second flow channel; and adjusting temperature of the structure on the second thermal module by the second thermal module, wherein: a fluid flow rate corresponding to the first flow channel is different from a fluid flow rate corresponding to the second flow channel. In an embodiment, the first thermal module includes an upper module and a first lower module, and the step of placing the structure on a second thermal module having a second flow channel includes: replacing the first lower module to a second lower module, so that the upper module and the second lower module constituting the second thermal module.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A structure, comprising:
a thermal module, having a flow channel; and
an electronic component intermediate, disposed on and thermally coupled to the thermal module.

2. The structure of claim 1, wherein the flow channel is located inside the thermal module.

3. The structure of claim 1, wherein the thermal module comprises a first module and a second module, and wherein:
the first module has a first top surface, a first bottom surface opposite to the first top surface, and a first combination hole penetrated through the first top surface and the first bottom surface;
the second module has a second top surface, a second bottom surface opposite to the second top surface, and a second combination hole penetrated through the second top surface and the second bottom surface; and
the first combination hole and the second combination hole are corresponded for combining the first module and the second module.

4. The structure of claim 1, wherein the thermal module comprises a first module and a second module, and wherein:
the second module has a top surface, and a recessed area on the top surface.

5. The structure of claim 4, wherein the first module has a bottom surface, and wherein a portion of the bottom surface corresponding to the recessed area is substantially flat.

6. The structure of claim 1, wherein the thermal module comprises a first module, a second module, and a third module, and wherein:
the second module is disposed between the first module and the third module; and
the second module has a trench, for forming the flow channel with the first module and the third module.

7. The structure of claim 6, wherein the thermal module further comprises at least one sealing component disposed between the first module and the second module, or disposed between the second module and the third module.

8. The structure of claim 1, wherein the thermal module has a guiding hole connecting to the flow channel.

9. The structure of claim 8, wherein the thermal module comprises a fluid connector, wherein an end of the guiding hole is located on a terminal of the fluid connector.

10. A thermal module kit, comprising:
a first thermal module, having a first flow channel; and
a second thermal module, having a second flow channel, wherein:
the first flow channel and the second flow channel are different in pattern, width or height.

11. The thermal module kit of claim 10, wherein:
an upper module and a first lower module constitute the first thermal module;
the upper module and a second lower module constitute the second thermal module; and
the first lower module and the second lower module are different.

12. The thermal module kit of claim 10, wherein:
a first upper module and a first lower module constitute the first thermal module;
a second upper module and a second lower module constitute the second thermal module; and
a surface of the first upper module facing to the first lower module and a surface of the second upper module facing to the second lower module are substantially flat.

13. The thermal module kit of claim 10, wherein:
a first upper module, a first lower module, and a first bottom module constitute the first thermal module, wherein first lower module is disposed between the first upper module and the first bottom module, and the first lower module has a first trench for forming the first flow channel with the first upper module and the first bottom module; and
a second upper module, a second lower module, and a second bottom module constitute the second thermal module, wherein second lower module is disposed between the second upper module and the second bottom module, and the second lower module has a second trench for forming the second flow channel with the second upper module and the second bottom module.

14. The thermal module kit of claim 13, wherein the first bottom module and the second bottom module are a same module having a guiding hole, wherein an aperture width at an end of the guiding hole is wider than widths of the first flow channel and the second flow channel.

15. A method for manufacturing an electronic component, comprising:
placing a structure on a first thermal module having a first flow channel; and
adjusting temperature of the structure on the first thermal module by the first thermal module.

16. The method of claim 15, further comprising:
placing the structure on a second thermal module having a second flow channel; and
adjusting temperature of the structure on the second thermal module by the second thermal module, wherein:
the first flow channel and the second flow channel are different in pattern, width or height.

17. The method of claim 16, further comprising:
placing the structure on a second thermal module having a second flow channel; and
adjusting temperature of the structure on the second thermal module by the second thermal module, wherein:
a highest temperature of the structure on the first thermal module is different a highest of the structure on the second thermal module; or
a lowest temperature of the structure on the first thermal module is different a lowest of the structure on the second thermal module.

18. The method of claim 16, further comprising:
placing the structure on a second thermal module having a second flow channel; and
adjusting temperature of the structure on the second thermal module by the second thermal module, wherein:
a temperature adjustment rate of the structure on the first thermal module is different a temperature adjustment rate of the structure on the second thermal module.

19. The method of claim 16, further comprising:
placing the structure on a second thermal module having a second flow channel; and
adjusting temperature of the structure on the second thermal module by the second thermal module, wherein:
a fluid flow rate corresponding to the first flow channel is different from a fluid flow rate corresponding to the second flow channel.

20. The method of claim 16, wherein the first thermal module comprises an upper module and a first lower module, and the step of placing the structure on a second thermal module having a second flow channel comprises:
replacing the first lower module to a second lower module, so that the upper module and the second lower module constituting the second thermal module.
